(19) United States
(12) Patent Application Publication
(10) Pub. No.: US 2007/0012861 A1
(43) Pub. Date: Jan. 18, 2007

(54) Solid-state imaging device

(75) Inventors: Tatsuo Onodera, Miyagi (JP); Tomohiro Sakamoto, Miyagi (JP)

Correspondence Address: BIRCH STEWART KOLASCH & BIRCH, PO BOX 747, FALLS CHURCH, VA, 22040-0747, US

(73) Assignee: FUJI PHOTO FILM CO., LTD.

(21) Appl. No.: 11/480,498

(22) Filed: Jul. 5, 2006

(30) Foreign Application Priority Data
Jul. 7, 2005 (JP) P. 2005-198851

(51) Int. Cl. H01L 27/00

(52) U.S. Cl. 250/208.1

(57) ABSTRACT

A solid-state imaging device comprises: a semiconductor substrate; and a plurality of photodiodes arranged in a surface of the semiconductor substrate, each of the photodiodes having a predetermined shape and being divided into: a first split pixel occupying a central region of a photo acceptance surface of each of the photodiodes; and a second split pixel occupying a peripheral region of each of the photodiodes except the first split pixel, wherein a transfer gate for the first split pixel and a transfer gate for the second split pixel in each of the photodiodes are provided in opposite positions of each of the photodiodes.

### BACKGROUND OF THE INVENTION

1. Field of the Invention

The present invention relates to a solid-state imaging device such as a CCD type image sensor or a CMOS type image sensor. Particularly, it relates to a solid-state imaging device provided with photodiodes for forming pixels respectively, wherein each of the photodiodes is formed so as to be divided into a plurality of parts.

2. Description of the Related Art

A solid-state imaging device mounted in a digital camera, etc. is provided with a large number of photodiodes for photoelectrically converting incident light. JP-A-2004-193762 (FIG. 4) has disclosed a solid-state imaging device provided with photodiodes each of which is divided into two, i.e. a first pixel and a second pixel different in sensitivity.

FIG. 5 is a view showing an example of division of each photodiode illustrated in JP-A-2004-193762 (FIG. 4). The solid-state imaging device is formed so that odd-numbered rows of photodiodes 1 are shifted by a half pitch from even-numbered rows of photodiodes 1, and that a vertical transfer path 2 meandering along a vertical direction is formed between horizontally adjacent ones of the photodiodes 1.

Each photodiode 1 is formed so as to be divided into a first pixel 1a and a second pixel 1b. This pixel division is performed by a pixel separation region 3 provided between the first pixel 1a and the second pixel 1b.

In the example illustrated in FIG. 5, each photodiode 1 shaped like a rhombus is divided into a large-area first pixel 1a and a small-area second pixel 1b. The first pixel 1a has a signal readout gate 1c in one side of the rhombic photodiode 1 and occupies a rectangular range in the center of the photodiode 1. The second pixel 1b is shaped like a “U” figure to follow the remaining three sides of the rhombic photodiode 1.

The reason why each second pixel 1b with low sensitivity is shaped like a “U” figure in this manner is that shading is prevented from being caused by deviation of low sensitivity signals detected by the second pixels 1b in accordance with the locations of the photodiodes 1 (such as upper right, upper left, lower right or lower left of the solid-state imaging device).

In the related-art solid-state imaging device shown in FIG. 5, a signal readout gate 1d for a second pixel 1b of a certain photodiode 1 is provided in a “side” vertically adjacent to a “side” in which a signal readout gate 1c for a first pixel 1a of the certain photodiode 1 is provided, so that photo acceptance charge of the first pixel 1a and photo acceptance charge of the second pixel 1b can be read out to one vertical transfer path 2.

In the related-art solid-state imaging device provided with photodiodes each of which is divided into a first pixel 1a and a second pixel 1b as shown in FIG. 5, there is a problem that a high readout voltage must be applied to a signal readout gate 1d when photo acceptance charge of each second pixel 1b is read out from the readout gate 1d to a vertical transfer path 2.

This is because the second pixel 1b is formed into a long and narrow shape (a “U” figure in the example of FIG. 5) and the readout gate 1d is provided in one end portion of the second pixel 1b so that a high readout voltage is required for moving photo acceptance charge stored in the other end portion side by a long distance and completely reading out the photo acceptance charge.

### SUMMARY OF THE INVENTION

An object of the invention is to provide a solid-state imaging device in which signals can be read out easily and rapidly even in the case where each split pixel is formed into a long and narrow shape for the purpose of avoiding shading.

The invention provides a solid-state imaging device having a semiconductor substrate, and a plurality of photodiodes arranged in a surface of the semiconductor substrate, each photodiode having a predetermined shape and being divided into a first split pixel and a second split pixel, the first split pixel occupying a central region of a photo acceptance surface of the photodiode, the second split pixel occupying a peripheral region of the photodiode except the first split pixel, wherein a transfer gate for the first split pixel and a transfer gate for the second split pixel in each photodiode are provided in opposite positions of the photodiode.

In the solid-state imaging device according to the invention, the predetermined shape is a rectangle; the transfer gate for the first split pixel is provided in one side of the rectangle; the second split pixel is formed into a shape along the remaining three sides of the rectangle except the one side; and the transfer gate for the second split pixel is provided in a central location of the three sides.

In the solid-state imaging device according to the invention, the photodiodes are arranged in the surface of the semiconductor substrate so that odd-numbered rows of photodiodes are shifted by a half pitch from even-numbered rows of photodiodes.

The solid-state imaging device according to the invention is that of a CCD type.

### BRIEF DESCRIPTION OF THE DRAWINGS

FIG. 1 is a typical view of a surface of a solid-state imaging device according to a first embodiment of the invention;

FIG. 2 is an enlarged view of important part of the solid-state imaging device shown in FIG. 1;

FIG. 3 is a typical view of a surface of a solid-state imaging device according to a second embodiment of the invention;

FIG. 4 is an enlarged view of important part of the solid-state imaging device shown in FIG. 3; and

FIG. 5 is an enlarged view of important part of a solid-state imaging device according to the related art.

### DETAILED DESCRIPTION OF THE INVENTION

An embodiment of the invention will be described below with reference to the drawings.

### First Embodiment

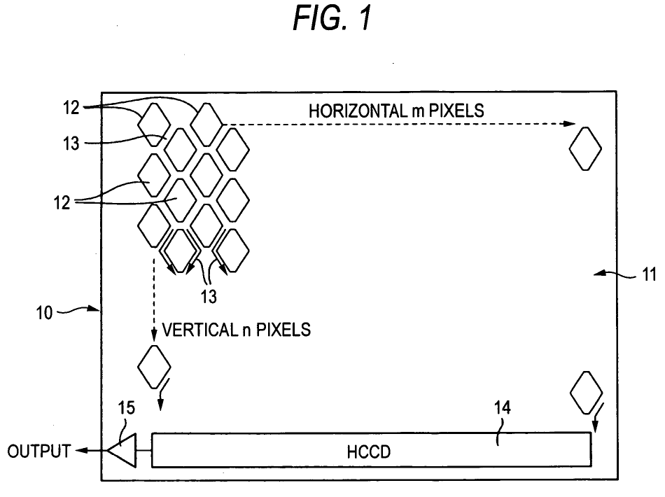

FIG. 1 is a typical view of a surface of a solid-state imaging device according to a first embodiment of the invention. The solid-state imaging device 10 according to this embodiment includes a semiconductor substrate, and a large number of photodiodes 12 (photoelectric conversion devices) 12 two-dimensionally arranged in a surface 11 of the semiconductor substrate.

The solid-state imaging device 10 as an example illustrated in FIG. 1 is formed so that even-numbered rows of photodiodes 12 are shifted by a half pitch from odd-numbered rows of photodiodes 12, and that a vertical transfer path (VCCD) 13 meandering in a vertical direction is provided between horizontally adjacent ones of the photodiodes 12.

A horizontal transfer path (HCCD) 14 is provided in a lower side portion of the semiconductor substrate surface 11, and an output amplifier 15 is provided in an output stage of the horizontal transfer path 14. Photo acceptance charge of each photodiode 12 is read out to a corresponding vertical transfer path 13 and transferred to the horizontal transfer path 14 through the vertical transfer path 13. The photo acceptance charge is further transferred along the horizontal transfer path 14. Then, a signal corresponding to the photo acceptance charge is output from the output amplifier 15.

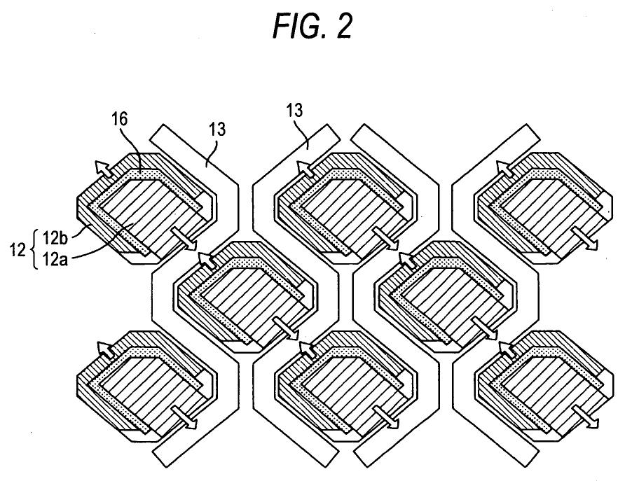

FIG. 2 is an enlarged typical view of the substrate surface corresponding to eight photodiodes 12. Each photodiode 12 is formed so as to be divided into a first pixel 12a and a second pixel 12b. This pixel division is performed by a pixel separation region 16 provided between the first pixel 12a and the second pixel 12b.

In the example illustrated in FIG. 2, each photodiode 12 shaped like a rhombus is divided into a large-area first pixel 12a and a small-area second pixel 12b. The first pixel 12a has a signal readout gate 12c in one side of the rhombic photodiode 12 and occupies a rectangular range in the center of the photodiode 12 in which incident light often concentrates. The second pixel 1b is formed into a long and narrow shape bent into a “U” figure along the remaining three sides of the rhombic photodiode 12.

The reason why each second pixel 12b with low sensitivity is formed into a long and narrow shape bent around a corresponding first pixel 12a with high sensitivity is that shading is prevented from being caused by deviation of low sensitivity signals detected by the second pixels 12b in accordance with the locations of the photodiodes 12 (such as upper right, upper left, lower right or lower left of the semiconductor substrate surface 11) as described above.

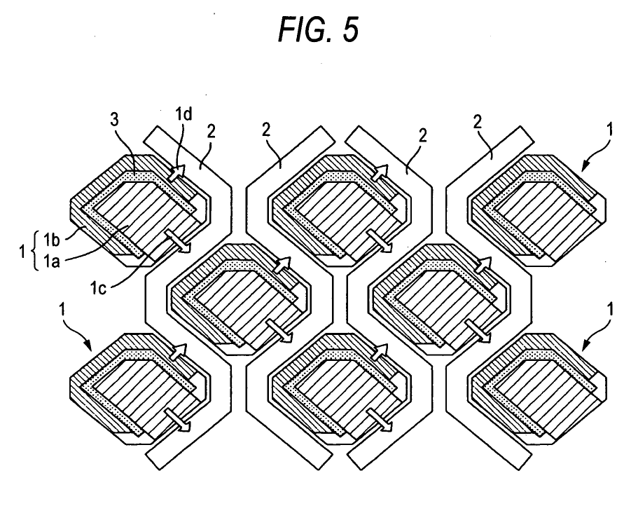

The solid-sate imaging device 10 according to this embodiment is configured so that photo acceptance charge of a first-pixel 12a of each photodiode 12 is read out from a readout gate 12c provided in a side of the first pixel 12a adjacent to a vertical transfer path 13, to the vertical transfer path 13 (to the vertical transfer path on the right side of the photodiode 12 in the example illustrated in FIG. 2). This is the same as in the related art shown in FIG. 5.

This embodiment is however configured so that photo acceptance charge of a second pixel 12b of the photodiode 12 is read out from a readout gate 12d provided in a location opposite to the readout gate 12c (in an opposite location by 180°) , to a vertical transfer path 13 (a vertical transfer path on the left side of the photodiode 12 in the example illustrated in FIG. 2) on a side opposite to a vertical transfer path 13 for reading out the photo acceptance charge of the first pixel 12a.

That is, in the solid-state imaging device 10 according to this embodiment, the distance between each readout gate 12d and each of opposite end portions of a corresponding second pixel 12b becomes short because the readout gate 12d is provided in the central position of the second pixel 12b formed into a long and narrow bent shape and having low sensitivity. Thus, all photo acceptance charges of the second pixels 12b can be read out to the vertical transfer paths 13 in a short time without necessity of applying a high readout voltage to the readout gates 12d because the moving distance of each photo acceptance charge is short.

When the solid state imaging device 10 shown in FIG. 2 is used for sensing an image, photo acceptance charge of the first pixel 12a of each photodiode 12 is first read out and transferred to the vertical transfer path 13 and output from the solid-state imaging device 10, and then, photo acceptance charge of the second pixel 12b of the photodiode 12 is read out and transferred to the vertical transfer path 13 and output. Image data obtained from the first pixels 12a and image data obtained from the second pixels 12b are combined by an image processing apparatus disposed in the rear stage of the solid-state imaging device. Thus, an image with a wide dynamic range is reproduced.

Because the aforementioned embodiment is configured so that photo acceptance charge of each split pixel having a photo acceptance surface bent or curved into a long and narrow shape is read out from a center position of the split pixel, there can be obtained an effect that the voltage applied to the readout gates to read out photo acceptance charges from the split pixels can be made low, and that no photo acceptance charge remains. As a result, it is easy to control driving of the solid-state imaging device, and it is also possible to attain reduction in consumed electric power because it is not necessary to supply a high voltage.

### Second Embodiment

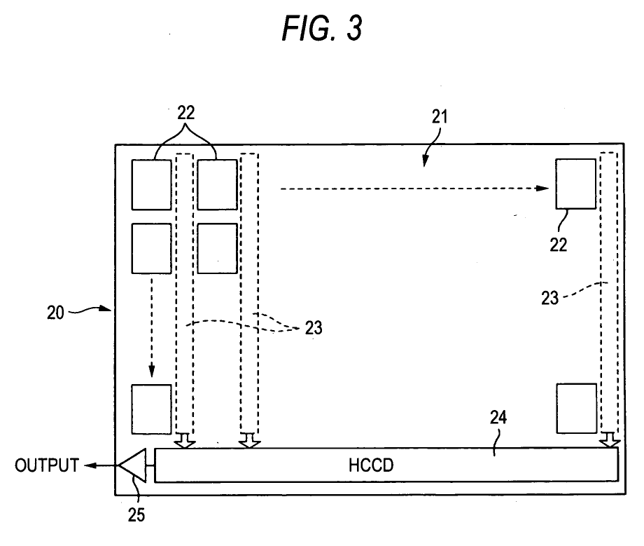

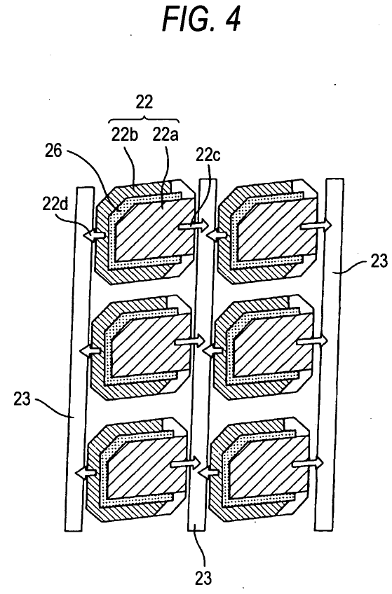

FIG. 3 is a typical view of a surface of a solid-state imaging device according- to a second embodiment of the invention. FIG. 4 is an enlarged view of important part of the surface of the solid-state imaging device. The solid-state imaging device 20 according to this embodiment includes a semiconductor substrate, and a large number of photodiodes 22 arranged in the form of a tetragonal lattice in a surface 21 of the semiconductor substrate. A vertical transfer path (VCCD) 23 extending vertically is provided between horizontally adjacent ones of the photodiodes 22.

A horizontal transfer path (HCCD) 24 is provided in a lower side portion of the semiconductor substrate surface 21, and an output amplifier 25 is provided in an output stage of the horizontal transfer path 24. Photo acceptance charge of each photodiode 22 is read out to a corresponding vertical transfer path 23 and transferred to the horizontal transfer path 24 through the vertical transfer path 23. After the photo acceptance charge is further transferred along the horizontal transfer path 24, a signal corresponding to the photo acceptance charge is output from the output amplifier 25.

Similarly to the photodiode 12 according to the first embodiment, each photodiode 22 provided in the solid-state imaging device 20 according to this embodiment is divided into a first pixel 22a and a second pixel 22b by a pixel separation region 26. The first pixel 22a occupies a rectangular range in the center of the photodiode 22. The second pixel 22b has a long and narrow shape and occupies a peripheral region of the photodiode 22 exclusive of a readout gate 22c of the first pixel 22a.

The example illustrated in FIG. 4 is configured so that photo acceptance charge of the first pixel 22a is read out to a vertical transfer path 23 on the right side of the photodiode 22 by the readout gate 22c of the photodiode 22 whereas photo acceptance charge of the second pixel 22b is read out to a vertical transfer path 23 on an opposite side (on the left side of the photodiode 22) by a readout gate 22d provided in a location opposite by 180° to the readout gate 22c.

Also in the solid-state imaging device provided with photodiodes which are arranged in the form of a tetragonal lattice on the surface of the semiconductor substrate and each of which is divided into pixels in this manner, all photo acceptance charges of the second pixels can be read out in a short time with the same readout voltage as that for the first pixels.

Although each of the aforementioned embodiments has been described on the case where each photodiode is shaped like a rhombus (in top view), any other shape than the rhombic shape may be used as the shape of the photodiode. As long as the readout gate of the second pixel formed into a long and narrow shape curved (in the case where the photodiode is shaped like a circle in top view) or bent (in the case where the photodiode is shaped like a polygon such as a rectangle in top view) and occupying a peripheral region of the photodiode exclusive of the readout gate of the first pixel is provided in a position opposite to the readout gate of first pixel while the first pixel occupies the central range of the photodiode, it is possible to obtain the same effect as that of the first or second embodiment.

Although the aforementioned embodiments have been described on the case where a CCD type solid-state imaging device is taken as an example, the invention is also applicable to an MOS type solid-state imaging device such as a CMOS type solid-state imaging device. In the case of an MOS type solid-state imaging device, signal readout lines provided for first pixels and second pixels respectively are brought into ohmic contact with a surface of a semiconductor substrate, so that signals corresponding to photo acceptance charges are read out. However, the signal readout positions of the first and second pixels may be arranged in the same manner as in the positional relation between the readout gates in each of the aforementioned embodiments.

According to the invention, signals of the second split pixels can be read out completely, easily and rapidly because the signals of the second split pixels are read out from the respective central places of the second split pixels each formed into a long and narrow shape.

The solid state imaging device according to the invention is useful as a solid-state imaging device mounted in a digital camera, a cellular phone, etc. because signals can be read out from split pixels easily and speedily even in the case where each photodiode is divided into the split pixels.

The entire disclosure of each and every foreign patent application from which the benefit of foreign priority has been claimed in the present application is incorporated herein by reference, as if fully set forth.

What is claimed is:

1. A solid-state imaging device comprising:
a semiconductor substrate; and
a plurality of photodiodes arranged in a surface of the semiconductor substrate, each of the photodiodes having a predetermined shape and being divided into: a first split pixel occupying a central region of a photo acceptance surface of each of the photodiodes; and a second split pixel occupying a peripheral region of each of the photodiodes except the first split pixel,
wherein a transfer gate for the first split pixel and a transfer gate for the second split pixel in each of the photodiodes are provided in opposite positions of each of the photodiodes.

2. A solid-state imaging device according to claim 1,
wherein: the predetermined shape is a rectangle; the transfer gate for the first split pixel is provided in one side of the rectangle; the second split pixel is formed into a shape along the remaining three sides of the rectangle except the one side; and the transfer gate for the second split pixel is provided in a central location of the three sides.

3. A solid-state imaging device according to claim 1,
wherein the photodiodes are arranged in the surface of the semiconductor substrate so that odd-numbered rows of photodiodes are shifted by a half pitch from even-numbered rows of photodiodes.

4. A solid-state imaging device according to claim 1,
wherein the solid-state imaging device is that of a CCD type.
